(19) United States
(12) Patent Application Publication
(10) Pub. No.: US 2024/0151780 A1
(43) Pub. Date: May 9, 2024

(54) IN-SITU ELECTROCHEMICAL CELL WITH SIMULTANEOUS THERMAL ANALYSIS

(71) Applicant: FRIEDRICH-SCHILLER-UNIVERSITÄT JENA, Jena (DE)

(72) Inventors: Lars Henning HESS, Jena (DE); Andrea BALDUCCI, Jena (DE); Beate FÄHNDRICH, Jena (DE); Marcus OSTERMANN, Jena (DE)

(21) Appl. No.: 18/281,458

(22) PCT Filed: Mar. 14, 2022
(86) PCT No.: PCT/EP2022/056569

§ 371 Date: Sep. 11, 2023

(30) Foreign Application Priority Data
Mar. 12, 2021 (DE) 10 2021 001 324.7

(51) Int. Cl. G01R 31/392; H01G 11/08; H01G 11/18; H01M 10/42; H01M 10/48; G01N 5/04; G01R 31/389

(52) U.S. Cl. CPC G01R 31/392; H01G 11/08; H01G 11/18; H01M 10/4285; H01M 10/486; G01N 5/04; G01R 31/389

(57) ABSTRACT

This document teaches a novel method for the characterization of electrochemical cells (5) in their operational timeframe (during charging/discharging). The electrochemical cell is placed in a thermogravimetric analyser and/or in a differential thermal analyser and/or in a dynamic differential calorimeter and/or simultaneous thermal analyser. The electrochemical cell is in physical contact with a measuring probe in the analyser and the cell is connected with several cables outside the analyser to a current source, preferably potentiostats and/or galvanostats. The interior of the cell comprises at least one current collector (15), one active material (20), one separator (25) and one electrolyte (27) and during an electronic measurement of the cell a response of the cell is measured.

### FIELD OF THE INVENTION

This application claims priority of the German Patent Application number DE 10 2021 001 324.7, filed on 12 Mar. 2021. The entire disclosure of the German Patent Application number DE 10 2021 001 324.7 is hereby incorporated herein by reference.

Electrochemical cells or electrochemical energy storage systems, such as batteries, double layer capacitors or supercapacitors are nowadays considered as promising energy storage devices which offer fast charging and discharging, a long cycle life and a high-power density [1]. Therefore, these electrochemical cells are suitable for applications where a fast energy delivery and uptake and good cyclability is needed.

### BACKGROUND OF THE INVENTION

High-power short-range transportation use cases, such as in vehicles including city buses and trams, which can be charged at every stop, are nowadays powered with electrochemical cells (including batteries or capacitors). However, it has been shown that the use of electrochemical cells might be problematic, and the electrochemical cells may fail due to poor thermal managing of the electrochemical cells whilst fast charging the electrochemical cells. This poor thermal management can result in the overheating of the electrochemical cells as a consequence of temperature mediated degradation processes occurring in these devices [2, 3].

In order to tackle these problems and issues, one could argue that more efficient thermal probing needs to be implemented into the existing devices. The drawbacks here are cost and complexity, while from lab scale data, heating can be predicted and modelled [4-6]. Most considerations on heat generation during the charging of the batteries are so far focused on the use of probing and modelling of these devices at a macro scale, for example by attaching multiple heat probes to a commercial device [2, 5, 7]. However, this approach has the drawback of long residence times for heat at boundaries. As a result, just the mean increase in temperature is measured, while the increase in temperature during individual charging and discharging cycles or pulses is diluted. Additionally, in such a setup it is impossible to detect and monitor the underlying temperature-mediated degradation processes, such as identifying the location of sources of the heat. To solve these problems, an in-operando calorimeter has been proposed in literature, which use is limited to probing the heat generation in the batteries. These calorimeters allow only time-dependent measurements of heat generation during electrochemical cycling in the batteries and to distinguish between the heat generated at each electrode of the batteries [8-12].

State of the art devices can probe heat, but these devices cannot probe heat together with other physical parameters at the same time. The devices also lack sensitivity and time resolution. Using these calorimeters, it is not possible to understand the fundamental underlying processes. Furthermore, in-situ electrochemical TGA systems to probe the mass change so far have not been developed due to the problem of outside interference. When the very sensitive balance of the TGA is connected via cables outside of the measurement chamber, interferences occur, which can render the measurement impossible.

There is therefore a need to probe the heat flow and the change of mass of electrochemical cells during operation in their operational timeframe. This probing will give deeper insight into the chemical reactions and failure mechanisms of the electrochemical devices, but without disturbing the electrochemical analysis as well as the thermal analysis of the cell.

### SUMMARY OF THE INVENTION

This document teaches a method for the characterization of electrochemical cells during their operational timeframe (including during charging/discharging). The electrochemical cell is placed in an analyser, such as a thermogravimetric analyser, a differential thermal analyser, a dynamic differential calorimeter or a simultaneous thermal analyser. The electrochemical cell is in physical contact with a measuring probe in the analyser and the electrochemical cell is connected with at least one cable outside of the analyser to a current source, such as but not limited to a potentiostats or a galvanostat. The interior of the electrochemical cell comprises at least one current collector, one active material, one separator and one electrolyte, whereby during an electronic measurement of the cell a response of the electrochemical cell is measured.

The document also teaches an apparatus for carrying out the method outlined above. The apparatus comprises a lid adapted for the analyser wherein a plurality of feedthroughs is provided through the lid for connecting the electrochemical cell to a power source.

The electrochemical cell of this document can be used inside classical thermogravimetric analysis (TGA) systems, differential thermal analysis (DTA) systems, differential scanning calorimetry (DSC) systems and simultaneous thermal analysis (STA) systems and help to monitor the interactions of degradation, heat flow, resistance and applied potential. The electrochemical cell can be used for electrochemical applications such as energy storage devices, e.g., batteries and fuel-cells, as well as for electrodeposition, and electro-catalysis.

The electrochemical cell of this document, combined with the analyser, is able to detect simultaneously heat and the change of mass and the evolution of gases from the electrochemical cell during an electrochemical measurement. It was not previously possible to detect these parameters, i.e., heat and change of mass, simultaneously. The electrochemical cell can also be utilized to detect individually the heat and/or the change of mass and/or the evolution of gases during electrochemical measurements.

The electrochemical cell is separated from the interfering surroundings by a specially adapted lid and is connected to the outside surroundings by very thin cables. This reduces the influence of noise during the measurement.

The term thermal “analysers” in this document will be used to include TGA/DSC/DTA and STA.

The design of the electrochemical cell can be implemented into the existing thermal analysers to probe the heat and the mass change caused by individual cycles and pulses. These thermal analysers are usually calibrated to detect very small changes in heat due to phase transitions and are suited for the detection of resistive (joule) heating and (small-scale) thermal runaway events. Furthermore, the thermal analysers are quite abundant in electrochemical material-development laboratories. By measuring the mass change of the active material (comprising carbon and an electrolyte), it is possible to derive and extrapolate information on gas production (development) and degradation progress including rates. Some thermal analysers are coupled to infrared spectrometers or gas chromatography coupled mass spectrometers [13], giving even a deeper insight into the produced gases and the degradation processes.

The operational timeframe is the timespan during which actions are performed on the electrochemical cell. During this time span, the electrochemical response of the electrochemical cell is measured, the heat flow is measured, the change of mass is measured, the gas composition can be measured by suitable procedures, e.g., infrared spectroscopy or mass spectrometry or gas chromatography coupled mass spectrometry.

Float measurements or “Floating” is a type of measurement, where the stability of an electrochemical cell is tested by holding electrochemical cell at a potential equal to the maximum rated cell voltage for a fixed amount of time. After holding the cell at this potential, the remaining energy density, capacitance and capacity of the electrochemical cell is determined to understand the degradation of the electrochemical cell and the stability of the electrochemical cell.

When implementing the electrochemical cell into the analyser, certain requirements need to be satisfied:
Heat transfer—The heat must be fast and evenly transferred between the electrochemical cell and a measuring probe.
Mass—The cell must be lightweight, due to TGA machine requirements.
Mounting—The parasitic heat transfer, contact resistance and total mass of cables must be minimal. The tension of the wires in the cables must be considered as this is easily underestimated.
Durability—The cell needs to endure heat as well as an aggressive chemical environment.

### DESCRIPTION OF THE DRAWINGS

FIG. 1a is a schematic drawing of the in-situ TGA/DTA/STA electrochemical cell.

FIG. 1b is a schematic drawing of another embodiment of the electrochemical cell.

FIG. 2 shows the baseline evaporation of the TGA electrochemical cell.

FIG. 3 shows the TGA/DTA signal of the in situ electrochemical cell.

FIG. 3a-c shows charging and voltage holding protocols during the measurement.

FIG. 4a shows the capacitance of an EDLC while holding the potentials.

FIG. 4b-c shows the variation in impedance after 15 h and 30 h.

FIG. 4d shows the cumulative heat flow recorded for a 2.5 V and 3.5 V cell.

FIG. 4e shows the mass retention in the electrochemical cell over the measurement set.

### DETAILED DESCRIPTION OF THE INVENTION

The invention will now be described on the basis of the drawings. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention.

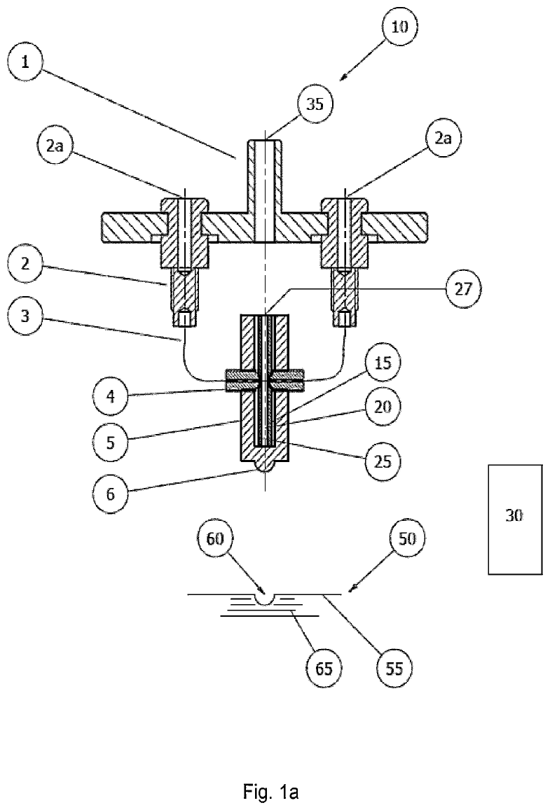

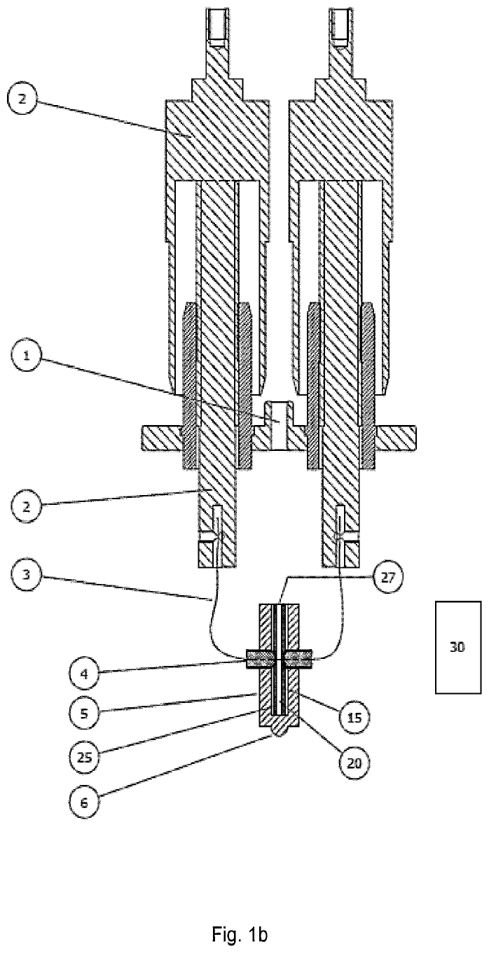

FIG. 1a shows a first example of an apparatus 10 with an electrochemical cell 5 used in the disclosure. The apparatus 10 comprises a lid 1 with an opening 1a for allowing gases to escape. The lid 1 includes at least one socket 2 with feedthroughs 2a for connecting cables 3 from the outside environment to the inside of the apparatus 10. Screws 4 are provided to keep a cell body 7, made for example of PEEK, of the electrochemical cell 5 in place. Electrodes are inserted into the main cavity of the cell body 7 and tensioned via the screws 4 to apply a contract pressure. The cell body 7 includes a retaining lug 6.

The electrodes comprise two current collectors 15 with activated carbon coating 20 separated by a separator 25, as will be explained in more detail below. The electrochemical cell 5 is connected to an external current source 30.

An analyser 50 is indicated at the bottom of FIG. 1a. The analyser 50 is one of thermogravimetric analyser, a differential thermal analyser, a differential dynamic calorimeter, or a simultaneous thermal analyser. The analyser 50 has a balance bar 55 with a recess 60 corresponding to the retaining lug 6 of the cell body 7. Electromagnetic coils 65 are mounted to the sides of the balance bar 55.

FIG. 1b shows a second example of the electrochemical cell 5 in a testing apparatus 10 in which the same reference numerals are used for the same elements as in FIG. 1a.

Electrochemical testing of the electrochemical cell 5 was performed with a SP-150 potentiostat from Biologic. The thermal analysis was performed with a STA 6000 simultaneous thermal analyser from PerkinElmer Inc. The gas flow was set to 20 ml N₂ per minute. The calibration of the STA 6000 was performed for nitrogen. The furnace temperature was set isothermal to 30° C. The STA 6000 cell was linked with a 50 μm enamelled copper wire to outside sockets. The current collectors were made of titanium metal and the cell body of polyether ketone (PEEK) resulting in a total weight 1100 mg.

The electrodes were produced by mixing 90% Kuraray YP-50F (activated carbon), 5% IMERYS Super C65 (nano carbon black) and 5% Dow Chemical Walocell CMC (carboxymethyl cellulose) with (for a total of 3 g) in 8 ml water to produce a slurry. This slurry was stirred in a dissolver for 30 min until the slurry yielded a substantially homogenous suspension. This substantially homogenous suspension was cast on an aluminium foil with a doctor blade set to 200 μm. Cut-outs for the electrodes were made from the aluminium foil with the homogenous suspension using a razor knife and a stencil. As a separator 25 between current collectors 15 in the electrodes, a Whatman GF/D glass fibre fabric with the same size as the cut-outs was used. As an electrolyte 27, a 1 M solution of 1-butyl-1-methyl-pyrrolidinium tetrafluoroborate Pyr14BF4 (Iolitec) in propylene carbonate (PC) (from Sigma Aldrich) was chosen. The electrolyte 27 was prepared in an argon-filled dry box (Labmaster Pro MBraun). All used solid materials were dried in a vacuum glass oven, while the solvent was dried using molecular sieves made from a zeolite with a pore size of 3 Å (Köstrolith). The water content of the electrolyte 27 was measured to be below 20 ppm by Karl Fischer titration.

From this coated aluminium foil and the cell body 7, the electrochemical cell 5 was assembled in an argon filled dry box and filled with 50-60 μL of the electrolyte 27. The screws 4 were hand-tightened with a screwdriver to enclose the coated aluminium foil, forming the current collectors 15, in the cell body 7. The amount of the active material, comprising activated carbon, was between 4 mg and 8 mg in the cell body 7. The typical weight of the loaded electrochemical cell 5 was around 1200-1250 mg.

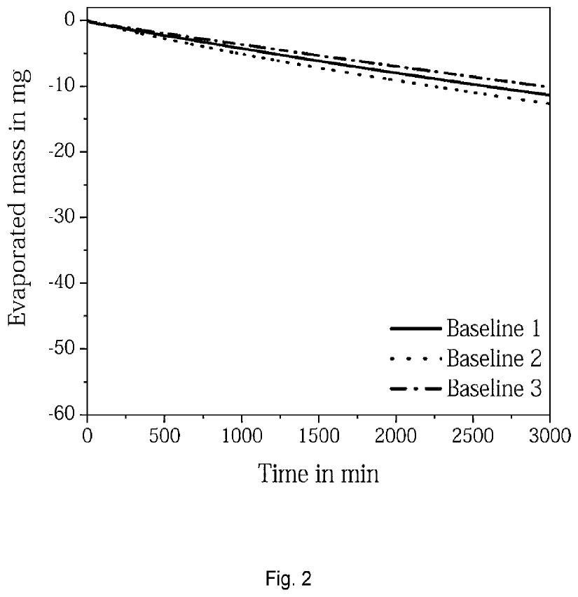

An in-situ STA cell can have an open top in the apparatus 10, allowing gases and decomposition products to evaporate from the STA electrochemical cell 5. However, the top of the apparatus 10 can be closed by a lid, cap, vent or a valve 1, which opens after reaching a specified opening pressure allowing for the accumulation of gas. This accumulation of gas can simplify later analysis. In open configuration the evaporation rate is determined by diffusion [14], solvent and the diameter of the electrochemical cell 5 and was measured to be constant for this set of experiments (FIG. 2).

The electrochemical cell 5 was electrochemically cycled with the following sequence: Firstly: five cycles of charging and discharging of the electrochemical cell at a current density of 1 A g⁻¹. The potential was held for three minutes at the max. target potential. Secondly 20 cycles of regular galvanostatic cycling at 1 A g⁻¹. Thirdly at a constant potential for 5 h.

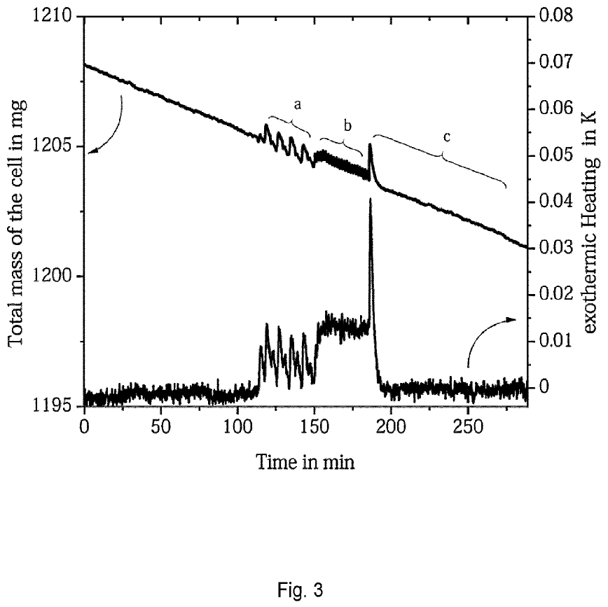

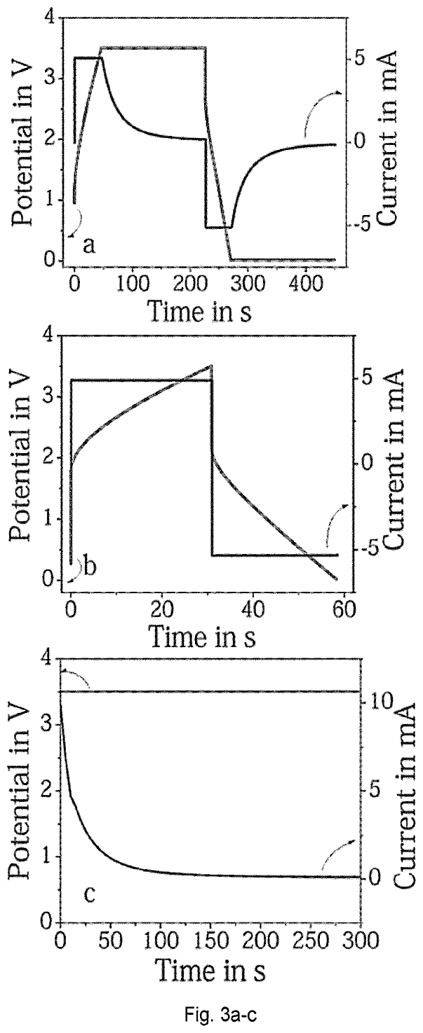

FIG. 3 shows the TGA signal (due to mass loss and exothermic heating) recorded from the electrochemical cell 5 (in this case being a supercapacitor and more particularly an electric double layer capacitor—EDLC) operating in the in-situ STA electrochemical cell 5 during galvanostatic charge-discharge tests (1 A g⁻¹) with and without a constant voltage step (FIG. 3a and FIG. 3b, respectively) as well as during a float test at 2.5 V (FIG. 3c). As shown, while the holding periods yielded a constant temperature and a constant loss of mass, a change in current had a massive effect on the system. As visible in the curve, the use of pulses with a constant voltage between charge and discharge (FIG. 3a) leads to a triangular shape in the heat flow. On the other hand, the use of a constant charge and discharge current (FIG. 3b) leads to a higher baseline heat flow but decreases the resolution of the individual currents due to overlap of the heating. If the electrochemical cell 5 can draw higher currents such as in the constant voltage step (FIG. 3c) the heat flow increases significantly for a short time and then relaxes proportionally with lower currents. It is interesting to observe that during the charge-discharge process an increase in the mass of the electrochemical cell 5 is observed. This unexpected increase is due to the electromagnetic field that is produced by the device during the testing process, and that generates currents in the order of 3-30 mA which are also detected by the very sensitive balance of the TGA. The balance of the thermal analyser is also able to sense the currents flowing towards the supercapacitor and can be used to read the current flowing inside the device.

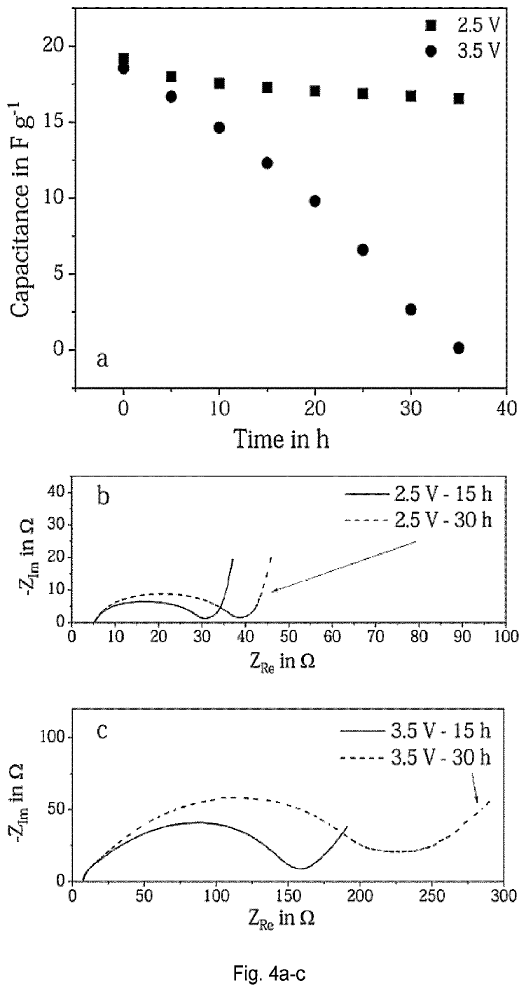

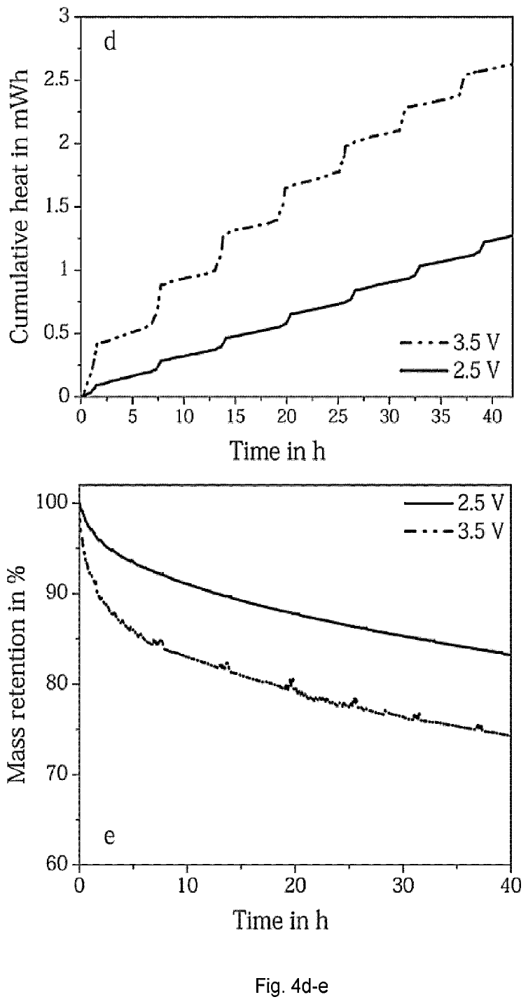

FIG. 4 shows the comparison of holding for 40 hours a cell to a stable potential (for lab scale as well as for commercial devices) of 2.5 V and to a demanding cell potential of 3.5 V. When the electrochemical cell 5 is held at 2.5 V, it loses 3 F g⁻¹ of its initial capacitance, while the electrochemical cell 5 that is kept at unstable potentials loses the complete capacitance. This degradation can be monitored by three parameters: Firstly, parasitic energy dissipated as heat (FIG. 4b), secondly loss in the mass by decomposition/evaporation (FIG. 4c), thirdly increase in resistance (FIG. 4d). The increase in the resistance and the increase in the heat flow build up each other and are interdependent. As shown, the impedance of the electrochemical cells 5 (EDLCs) operating at 2.5 V did not change significantly over 40 hours, as expected from the variation of the capacitance discussed above. On the contrary, the charge transfer resistance of the electrochemical cell 5 operating at 3.5 V increased significantly over the time of the floating test and already after 15 h became more than four times higher than that observed in the electrochemical cell operating at 2.5 V. This increase is clearly indicating the occurrence of faradaic processes within the electrochemical cell 5 associated with the electrolyte decomposition and solvent evaporation, which are leading to a fast reduction of the storage capability of the electrochemical cells 5. The occurrence of these processes is clearly visible in FIG. 4d, which is comparing the cumulative heat flow recorded for two different ones of the electrochemical cells 5, where the potential has been varied. As shown, after 5 h the cumulative heat flow in the electrochemical cell 5, i.e., EDLC, operating at 2.5 V was in order of 0.1 mWh, while that of the EDLC working at 3.5 V was ca. 0.5 mWh. This difference is clearly indicating that the applied potential has an impact on the heat flow of the EDLCs and that after a few hours (e.g., five hours) the heat flow of the EDLCs floated at high voltage is significantly larger (5 times) than that of the EDLC operating at 2.5 V. At the end of the test (after 40 h) the heat flow of the EDLC floated at 2.5 V was 1.2 mWh, corresponding to an increase of 0.03 mW each hour. After the same time, the heat flow of the EDLC floated at 3.5 V was 2.5 mWh, corresponding to an increase of 0.06 mW each hour.

### Acknowledgement of Financial Support

This work was supported by the Deutsche Forschungsgemeinschaft (DFG) within the projects “The combined use of computational screening and electrochemical characterization for the identification of new electrolyte components for supercapacitors” (BA 4956/5-1) and “EDLstruct” (BA4956/8-1).

### REFERENCES

1. Miller, J. R., Perspective on electrochemical capacitor energy storage. Applied Surface Science, 2018. 460: p. 3-7.
2. Miller, J. R., Electrochemical capacitor thermal management issues at high-rate cycling. Electrochimica Acta, 2006. 52(4): p. 1703-1708.
3. Miller, J. R. and A. F. Burke, Electrochemical capacitors: challenges and opportunities for real-world applications. The Electrochemical Society Interface, 2008. 17(1): p. 53.
4. Gualous, H., H. Louahlia, and R. Gallay, Supercapacitor Characterization and Thermal Modelling With Reversible and Irreversible Heat Effect. IEEE Transactions on Power Electronics, 2011. 26(11): p. 3402-3409.
5. Gualous, H., et al., Supercapacitor Thermal Modeling and Characterization in Transient State for Industrial Applications. IEEE Transactions on Industry Applications, 2009. 45(3): p. 1035-1044.
6. d′Entremont, A. L. and L. Pilon, Thermal effects of asymmetric electrolytes in electric double layer capacitors. Journal of Power Sources, 2015. 273: p. 196-209.
7. Schiffer, J., D. Linzen, and D. U. Sauer, Heat generation in double layer capacitors. Journal of Power Sources, 2006. 160(1): p. 765-772.
8. Dandeville, Y., et al., Measuring time-dependent heat profiles of aqueous electrochemical capacitors under cycling. Thermochimica Acta, 2011. 526(1): p. 1-8.
9. Pascot, C., et al., calorimetric measurement of the heat generated by a Double-Layer Capacitor cell under cycling. Thermochimica Acta, 2010. 510(1): p. 53-60.
10. Likitchatchawankun, A., et al., Effect of temperature on irreversible and reversible heat generation rates in ionic liquid-based electric double layer capacitors. Electrochimica Acta, 2020. 338: p. 135802.
11. Munteshari, O., et al., Effects of Constituent Materials on Heat Generation in Individual EDLC Electrodes. Journal of The Electrochemical Society, 2018. 165(7): p. A1547-A1557.
12. Munteshari, O., et al., Isothermal calorimeter for measurements of time-dependent heat generation rate in individual supercapacitor electrodes. Journal of Power Sources, 2018. 374: p. 257-268.
13. Hess, L. H., L. Wittscher, and A. Balducci, The impact of carbonate solvents on the self-discharge, thermal stability and performance retention of high voltage electrochemical double layer capacitors. Physical Chemistry Chemical Physics, 2019.
14. Roger, K., E. Sparr, and H. Wennerström, Evaporation, diffusion and self-assembly at drying interfaces. Physical Chemistry Chemical Physics, 2018. 20(15): p. 10430-10438.
15. Hess, L. H. and A. Balducci, 1,2-butylene carbonate as solvent for EDLCs. Electrochimica Acta, 2018. 281: p. 437-444.

### REFERENCE NUMERALS

1 lid
1a opening
2 sockets for lab connectors
2a feedthrough
3 cable/wire
4 screws
5 electrochemical cell
6 retaining lug
7 cell body
10 apparatus
12 apparatus body
15 current collector
20 activated carbon coating
25 separator
27 electrolyte
30 current source
50 analyser
55 balance bar
60 recess
65 electromagnetic coils

1. A method for temporal characterisation of electrochemical cells (5) in cycling operation, wherein the electrochemical cell (5) is used in an analyser, the electrochemical cell has physical contact with a thermal measuring probe and is connected with a plurality of wires (3) outside the analyser to a current source (30), preferably potentiostats and/or galvanostats, wherein the interior of the electrochemical cell (5) comprises at least one current collector (15), active material (20), a separator (25) and electrolyte 27; and
during an electronic measurement of the electrochemical cell (5), a response of the electrochemical cell (5) is measured.

2. The method according to claim 1, wherein the response of the electrochemical cell (5) is one of impedance spectroscopy, by charging and/or discharging, by cyclic voltammetry, h floating, by pulsed charging and/or discharging, by amperometry and/or by voltammetry.

3. The method according to claim 1, characterised in that the response of the electrochemical cell (5) is measured in terms of change in temperature and/or cell mass and/or analysis of effluent gases.

4. The method according to claim 1, wherein the analyser (50) is one of thermogravimetric analyser, a differential thermal analyser, a differential dynamic calorimeter, or a simultaneous thermal analyser.

5. The method according to claim 1, wherein the electronic measurement is carried out in a cycling operation.

6. An apparatus (10) for measuring properties of an electrochemical cell (5) located in an electrolyte (27) within the apparatus (10), wherein the apparatus (10) comprises an apparatus body (12) with a lid (1) adapted to fit the apparatus body (10) and feedthroughs (2a) are provided through the lid (1) for one or more wires (3) to connect the electrochemical cell (5) to a current source (30), and wherein the 12 electrochemical cell (5) comprises current collectors (15) with activated carbon coating (20) separated by a separator (25) in the electrolyte (27).

7. The apparatus (10) according to claim 6, characterised in that the one or more wires (3) can be adjusted in length in the apparatus (10).

8. The apparatus (10) according to claim 6, wherein the length adjustment is carried out by means of screws or built-in measuring screws located in the lid (1) and make the accommodation of the wires (3) adjustable in height.

9. The apparatus (10) according to claim 6, wherein a contact pressure is established between current collectors (15) and the cables (3) within the electrochemical cell (10) by means of screws (4) which are tightened against each other and thus apply pressure to the current collectors (15).

10. The apparatus (10) according to claim 6, wherein for heat transfer from the electrochemical cell (10) to an analyser (50), a retaining lug (60) is provided on the electrochemical cell (10) which is adapted to a corresponding recess (60) in the analyser (50).

11. The apparatus according to claim 6, characterised in that an opening (1a) is provided in the lid (1) for the escape of gases flowing out of the apparatus (10) from the electrochemical cell (5).
